(19) United States
(12) Patent Application Publication
(10) Pub. No.: US 2011/0049468 A1
(43) Pub. Date: Mar. 3, 2011

(54) LED AND LED DISPLAY AND ILLUMINATION DEVICES

(75) Inventor: Yosuke Mizuyama, Newton, MA (US)

(73) Assignee: Panasonic Corporation, Osaka (JP)

(21) Appl. No.: 12/547,023

(22) Filed: Aug. 25, 2009

(51) Int. Cl. H01L 33/00

(52) U.S. Cl. 257/13; 257/84; 438/24; 257/14; 257/88; 257/E33.005; 257/E33.077; 257/E33.045

(57) ABSTRACT

Light emitting chips, light emitting unit cells and methods of forming light emitting chips are provided. A light emitting chip includes a light emission structure having a p-type semiconductor layer, an n-type semiconductor layer, and an active layer therebetween. At least one light emitting unit is formed from the light emission structure including a light emitting diode (LED) and a plurality of light receiving diode (LRD) portions. The LRD portions are serially connected and configured to surround the LED portion. The LRD portions are optically coupled to the LED portion to receive total internal reflection (TIR) light from the LED portion and convert the TIR light to a photocurrent.

### FIELD OF INVENTION

The present invention relates to light emitting diodes (LEDs) and, more particularly, to light emitting unit cells and light emitting chips which recycle total internal reflection (TIR) light as a photocurrent source, and methods of forming the same.

### BACKGROUND OF THE INVENTION

Light emitting diodes (LEDs) generally convert electrical energy to light, and are known to be used as light sources. For example, LEDs may be used in full-color displays, image scanners, optical communication systems and various signal systems. LEDs are generally formed from semiconductor materials and typically include an active layer of semiconductor material located between two oppositely doped layers. When a bias is applied across the doped layers, holes and electrons are injected into the active layer, where they recombine to generate light. The light generated by the active region may be emitted in all directions and may escape from the LED through any exposed surfaces. The material of the active layer may be selected for emission of a particular wavelength of light. For example, gallium nitride (GaN) and zinc selenide (ZnSe) semiconductor materials may be used to emit green or blue light. Other examples of semiconductor materials include gallium phosphide (GaP) for green light, gallium arsenide phosphide (GaAsP) for yellow, orange and red light, and gallium aluminum arsenide (GaAlAs) for red light.

The efficiency of conventional LEDs may be limited by their inability to emit all of the light that is generated by the active layer. When an LED is energized, the light that is emitted from the active layer may reach the emitting surfaces/adjacent surfaces at many different angles. LEDs are typically formed from semiconductor materials having relatively high refractive indices (for example, a refractive index of about 2.2-3.8) compared to a refractive index of air (of about 1.0). According to Snell's law, light traveling from a region with a high index of refraction (the semiconductor material) to a region with a low index of refraction (air) that is less than a critical angle (relative to the surface normal direction) may propagate out of the LED. Light that reaches the surface at an angle greater than the critical angle does not pass, but instead experiences total internal reflection (TIR). Because of total internal reflection, much of the light generated by conventional LEDs is not emitted, thereby reducing the external quantum efficiency of the LED.

### SUMMARY OF THE INVENTION

The present invention relates to light emitting chips and methods of forming light emitting chips. The light emitting chip includes a light emission structure comprising a p-type semiconductor layer, an n-type semiconductor layer and an active layer between the p-type semiconductor layer and the n-type semiconductor layer. The light emitting chip includes at least one light emitting unit comprising a light emitting diode (LED) portion formed from the light emission structure and a plurality of light receiving diode (LRD) portions formed from the light emission structure. The plurality of LRD portions are serially connected and configured to surround the LED portion. The plurality of LRD portions are optically coupled to the LED portion to receive total internal reflection (TIR) light from the LED portion and are configured to convert the TIR light to a photocurrent.

The present invention also relates to a light emitting unit cell comprising a first light emitting diode (LED) electrically connected to a power source, a plurality of light receiving diodes (LRDs) connected in series and a second LED. The plurality of LRDs are optically coupled to the first LED to receive total internal reflection (TIR) light from the first LED and are configured to convert the TIR light to a photocurrent. The second LED is electrically connected in parallel with the plurality of LRDs.

The present invention further relates to a light emitting unit cell comprising a light emitting diode (LED) electrically connected to a power source and a plurality of light receiving diodes (LRDs) connected in series. The plurality of LRDs are optically coupled to the LED to receive total internal reflection (TIR) light from the LED and are configured to convert the TIR light to a photocurrent. The plurality of LRDs feed back the photocurrent to the LED.

### BRIEF DESCRIPTION OF THE DRAWINGS

The invention may be understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIG. 1A (Prior Art) is a top-plan view diagram of a conventional LED;

FIG. 1B (Prior Art) is a cross-section diagram along lines 1B-1B′ of the conventional LED shown in FIG. 1A;

FIG. 2 is a cross-section diagram of a portion of an LED illustrating reflection of light rays within the LED and propagation of light rays out of the LED;

FIG. 3 is a circuit diagram of an exemplary light emitting unit cell, according to an example embodiment of the present invention;

FIG. 4 is a top-plan view diagram of a structure of an exemplary light emitting unit cell shown in FIG. 3, according to an example embodiment of the present invention;

FIGS. 5A, 5B, 5C, 5D, 5E, 5F and 5G are respective cross-section and top-plan views diagrams illustrating an exemplary method of forming a light emitting chip, according to an embodiment of the present invention;

FIG. 6 is a cross-section diagram along lines 6-6′ of the exemplary light emitting chip shown in FIG. 5G, according to an embodiment of the present invention;

FIGS. 7A and 7B are graphs of theoretical extraction efficiency for an exemplary light emitting chip for different conversion efficiencies, according to an embodiment of the present invention;

FIG. 8 is a circuit diagram of an exemplary light emitting unit cell, according to another embodiment of the present invention;

FIG. 9 is a top-plan view diagram of a structure of the light emitting unit cell shown in FIG. 8, according to another embodiment of the present invention;

FIGS. 10A, 10B, 10C, 10D, 10E and 10F are top-plan views diagrams illustrating an exemplary method of forming a light emitting chip, according to another embodiment of the present invention;

FIG. 11A is a cross-section diagram along lines 11A-11A′ of the exemplary light emitting chip shown in FIG. 10F, according to another embodiment of the present invention;

FIG. 11B is a cross-section diagram along lines 11B-11B′ of the exemplary light emitting chip shown in FIG. 10F, according to another embodiment of the present invention;

FIG. 12 is a graph of extraction efficiency for an exemplary light emitting chip for different conversion efficiencies, according to an exemplary embodiment of the present invention; and

FIG. 13 is a top-plan view diagram of an exemplary micro-pixelated LED, according to another embodiment of the present invention.

### DETAILED DESCRIPTION OF THE INVENTION

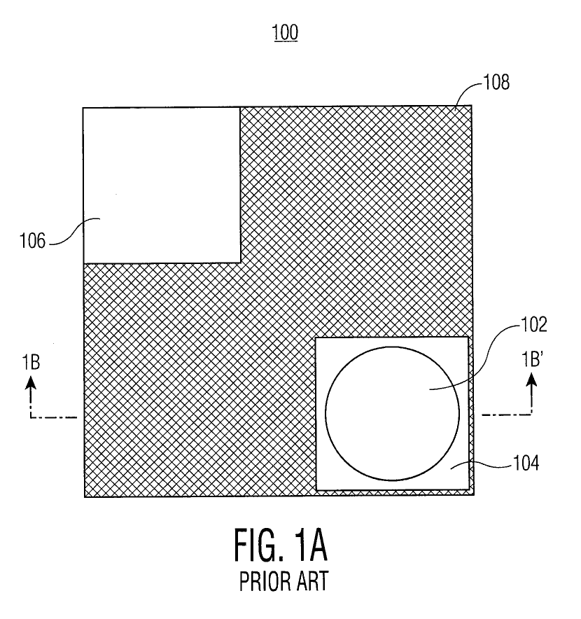

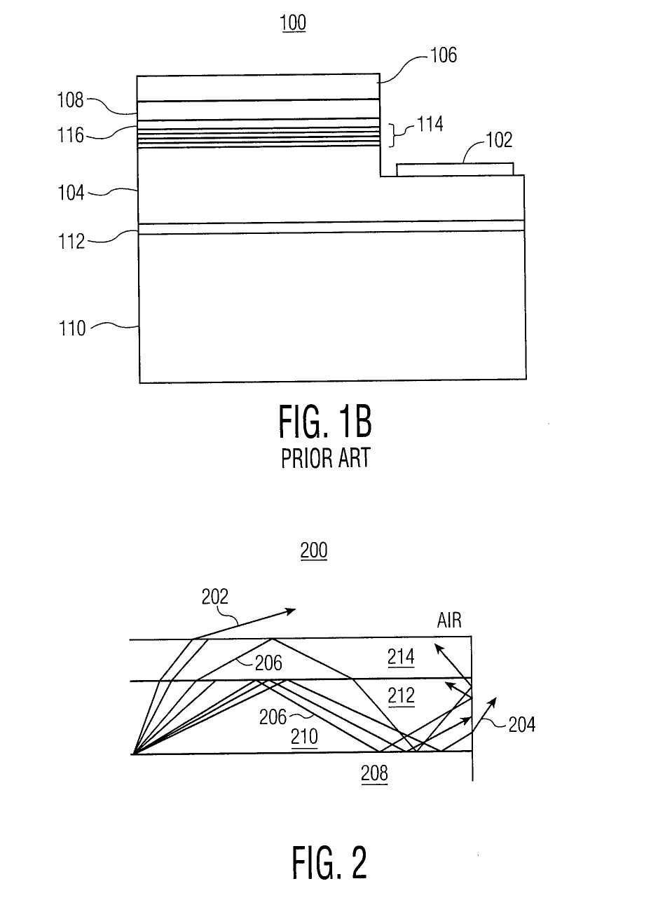

Referring to FIGS. 1A and 1B, a conventional LED 100 is shown. In particular, FIG. 1A is a top-plan view diagram of conventional LED 100 and FIG. 1B is a cross-section diagram of LED along lines 1B-1B′.

Conventional LED 100 includes substrate 110, buffer layer 112, n-type GaN layer 104, active layer 114 containing a multi-quantum well (MQW) structure, p-type GaN layer 116 and transparent electrode 108, which are sequentially laminated on substrate 110. Transparent electrode 108 may be used, for example, to enhance a current spreading effect.

Portions of transparent electrode 108, p-type layer 116 and active layer 114 may be removed by mesa-etching such that a portion of the upper surface of n-type layer 104 is exposed. A negative electrode (n-electrode) 102 is formed on the exposed upper surface of n-type layer 104. A positive electrode (p-electrode) 106 is formed on an upper surface of transparent electrode 108.

In active layer 114, electrons and holes are recombined so as to generate and emit light. The MQW structure of active layer 114 is formed by alternately laminating well layers and barrier layers (not shown). The well layer includes a semiconductor layer with a smaller band gap than n-type layer 104, p-type layer 116, and the barrier layer, thereby providing quantum wells in which electrons and holes may be recombined.

Referring to FIG. 2, a portion of an LED 200 is shown. LED 200 includes n-type layer 208, active layer 210, p-type layer 212 and transparent electrode 214. FIG. 2 illustrate the propagation of light generated from active layer 210. Light generated by active layer 210 may propagate out of LED 200 as light ray 202 or light ray 204, for angles less than the critical angle (relative to the surface normal direction). The remainder of light rays 206 have an angle greater than the critical angle, and experience TIR. In general, most of the generated light inside of active layer 210 may be trapped inside LED 200 due to total internal reflection, without escaping outside to be extracted. Accordingly, the extraction efficiency of conventional LEDs tends to be poor (for example, about 40%).

One conventional technique to improve the extraction efficiency is related to ray redirection using, for example, surface roughening, gratings and volume holograms to circumvent TIR. However, these techniques tend to improve the extraction by no more than about 60% from 40% (which is only a 50% increase in efficiency).

In general, LED efficiency may include an internal quantum efficiency, an extraction efficiency and an external quantum efficiency (also referred to herein as power efficiency). The internal quantum efficiency, extraction efficiency and external quantum efficiency may be defined by respective equations (1)-(3), below as:

$$\begin{matrix}internal quantum efficiency = \frac{\# of photons created inside L E D per unit time}{\# of electrons injected per unit time} & ( 1 ) \\ extraction efficiency = \frac{\# of photons emittied outside L E D per unit time}{\# of photons created inside L E D per unit time} & ( 2 ) \\ external quantum efficiency = \frac{\# of photons emitted outside L E D per unit time}{\# of electrons injected per unit time} = p ower efficiency = \frac{optical output power emitted outside L E D}{injected electrical power} & ( 3 )\end{matrix}$$

Because the external quantum efficiency (power efficiency) is the product of internal quantum efficiency (eq. 1) and extraction efficiency (eq. 2), the external quantum efficiency may be improved by improving either the internal quantum efficiency or the extraction efficiency.

As shown in FIG. 2, light ray 202 is emitted from a top surface of transparent electrode 214 and propagates out of LED 200. Light ray 204 also propagates from a lateral surface of LED 200, such as through active layer 210 and/or p-type layer 212. According to aspects of example embodiments of the present invention, exemplary light emitting unit cells includes a plurality of light receiving diodes (LRDs) optically coupled to the LED to absorb TIR light rays 206 from the LED. The LRDs may convert the absorbed light to a photocurrent. The light emitting unit cell may use the photocurrent to power a further LED or may feed the photocurrent back to the LED. Accordingly, by reusing the TIR light as an applied photocurrent, the current-voltage (I-V) characteristics of the exemplary light emitting unit cell may be improved, such that a lower current may be used to obtain a same light output. Exemplary light emitting unit cells of the present invention may theoretically achieve as much as 80% extraction efficiency, resulting in a 100% increase in extraction efficiency relative to a conventional LED.

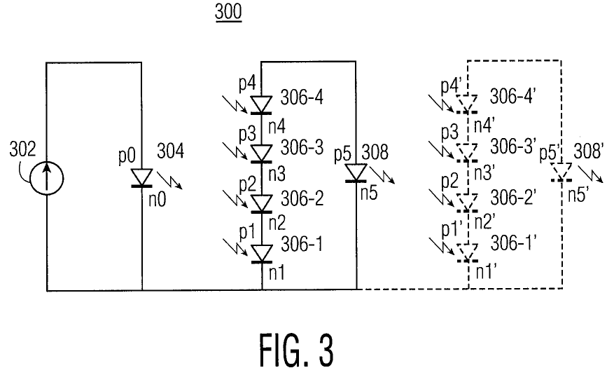

Referring next to FIG. 3, a circuit diagram of an example light emitting unit cell 300 is shown. Light emitting unit cell 300 includes first LED 304 connected in parallel with power source 302. Light emitting unit cell 300 also includes a plurality of light receiving diodes (LRDs) 306 which are optically coupled to first LED 304 and electrically connected to second LED 308.

LRDs 306-1, 306-2, 306-3, 306-4 are connected to each other in series. Anode p4 of LRD 306-4 is electrically connected to anode p5 of second LED 308. Cathode n1 of LRD 306-1 is electrically connected to cathode n5 of second LED 308 and cathode n0 of first LED 304.

In operation, first LED 304 is powered by power source 302 and second LED 308 is powered by LRDs 306 (i.e., LRDs 306 supply current and voltage to second LED 308 for light emission). LRDs 306 may absorb light trapped inside the layers of first LED 304 (i.e., due to TIR) and convert the absorbed light to a photocurrent. LRDs 306 may be configured to absorb the TIR light without emitting light. Thus, each of LRDs 306 may act as a photodiode. Accordingly, light emitting unit cell 300 may recycle photocurrent that would be lost due to TIR and apply the photocurrent to power second LED 308.

Although four LRDs 306 are shown in FIG. 3, it is understood by the skilled person that light emitting unit cell 300 may include two or more LRDs 306 configured to absorb TIR light from first LED 304, to provide a suitable photocurrent for powering second LED 308. Because second LED 308 may also lose a portion of the respective light emission due to TIR, further LRDs 306′ and a third LED 308′ (shown in phantom) may also be included in light emitting unit cell 300, coupled to second LED 308.

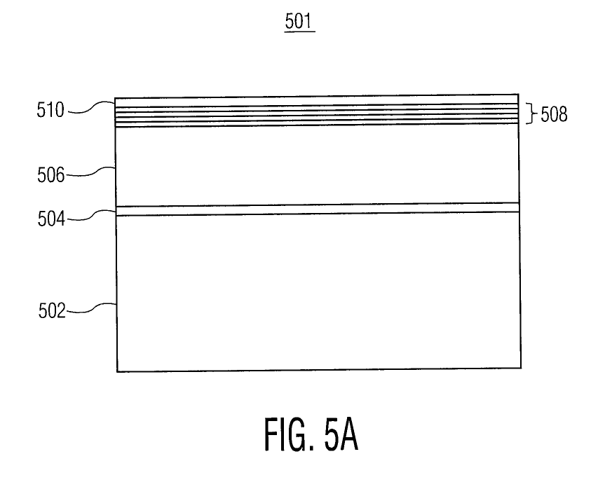

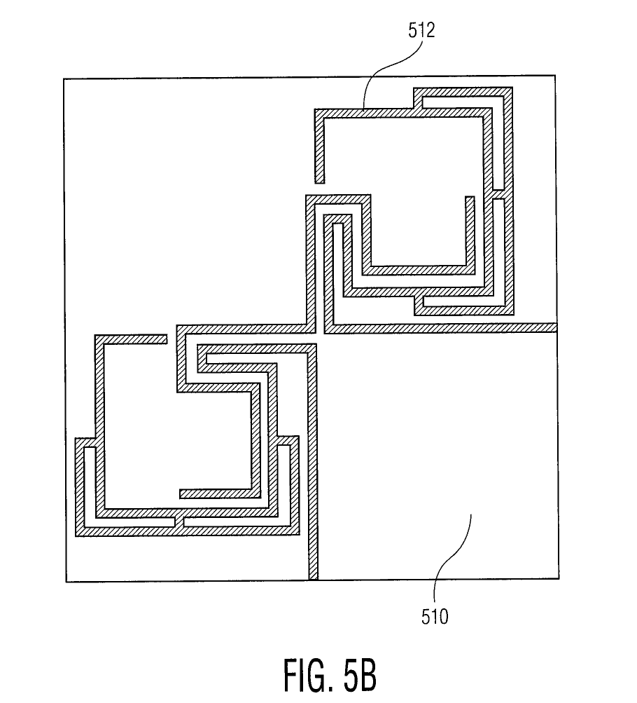

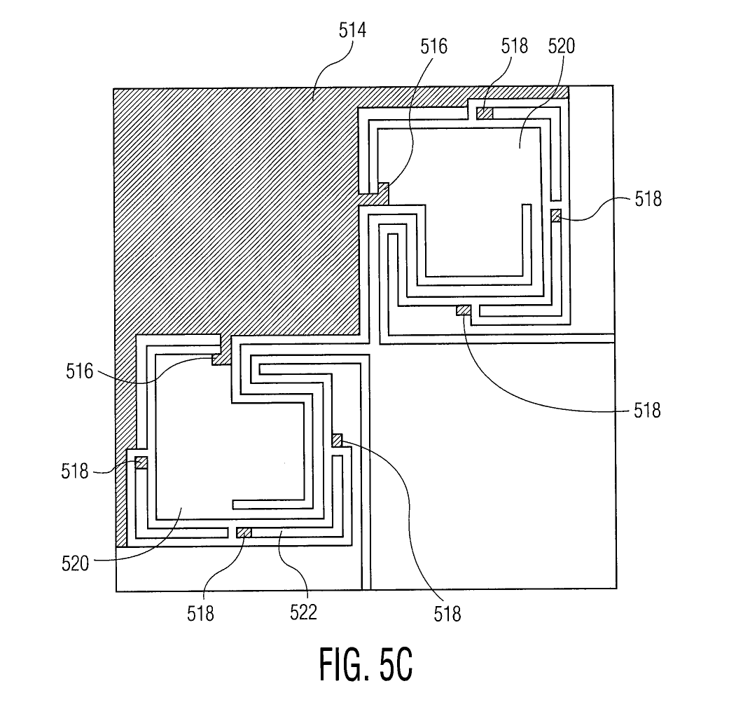

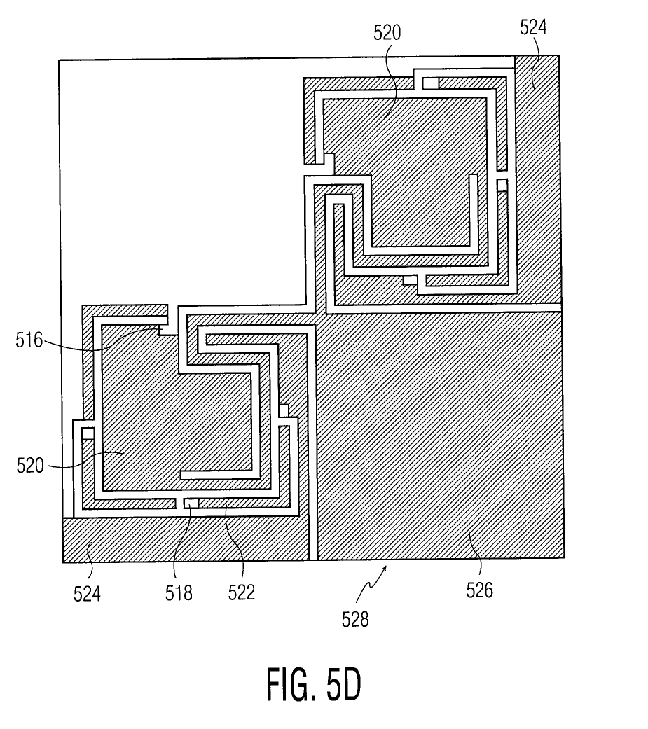

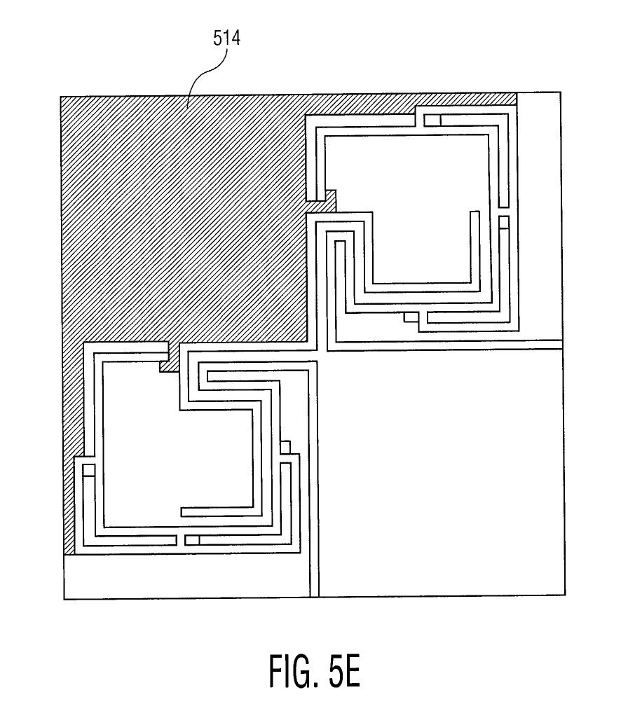

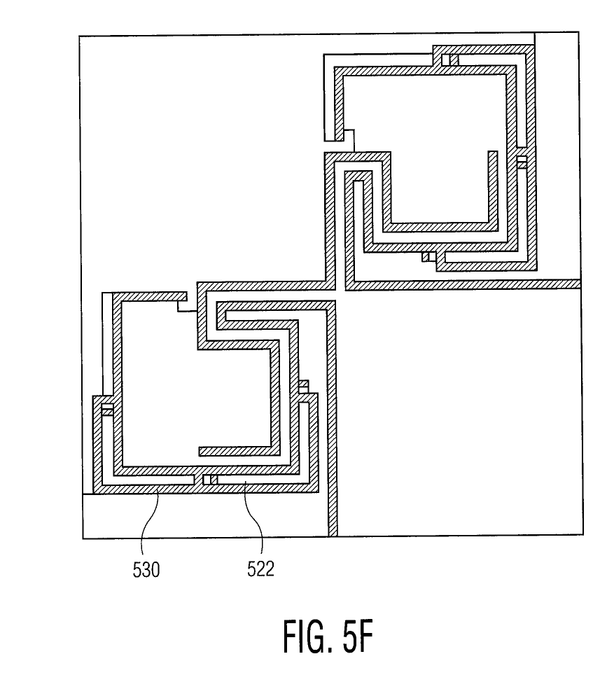

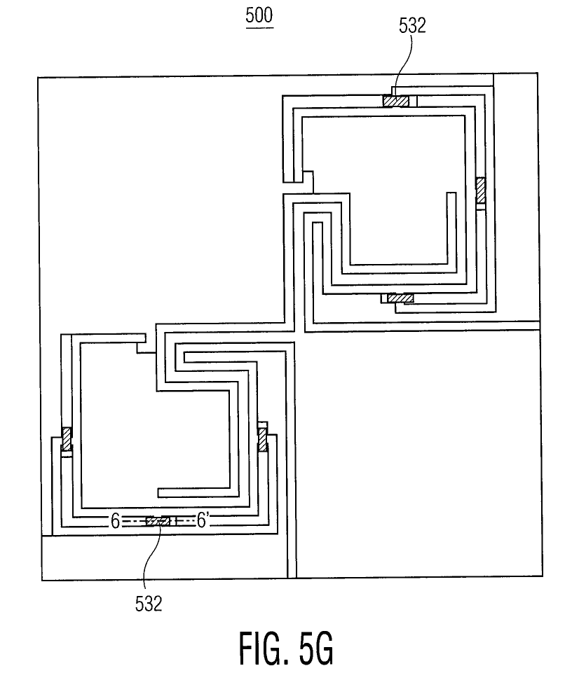

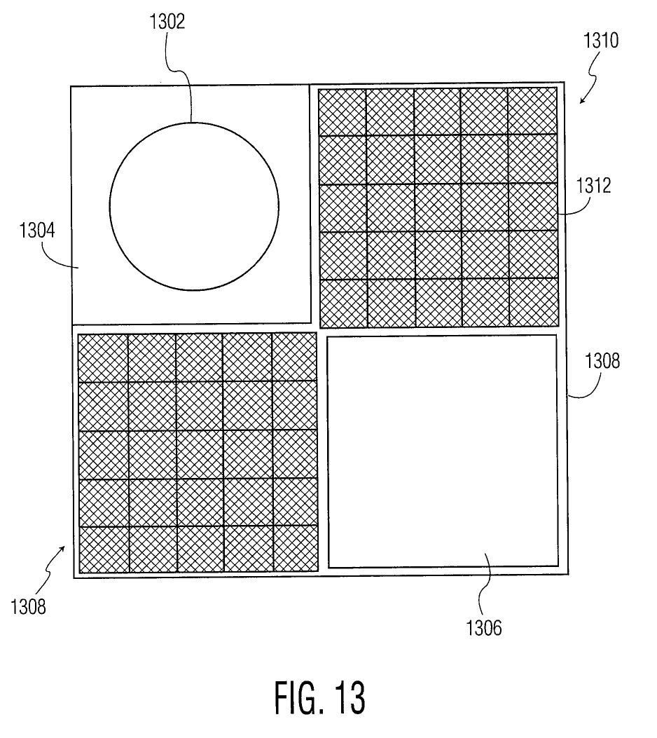

Although one light emitting unit cell 300 is shown in FIG. 3, an LED chip (described below with respect to FIGS. 5A-5G) may include a plurality of unit cells (such as described below with respect to FIG. 13), which is referred to herein as a micro-pixelated LED.

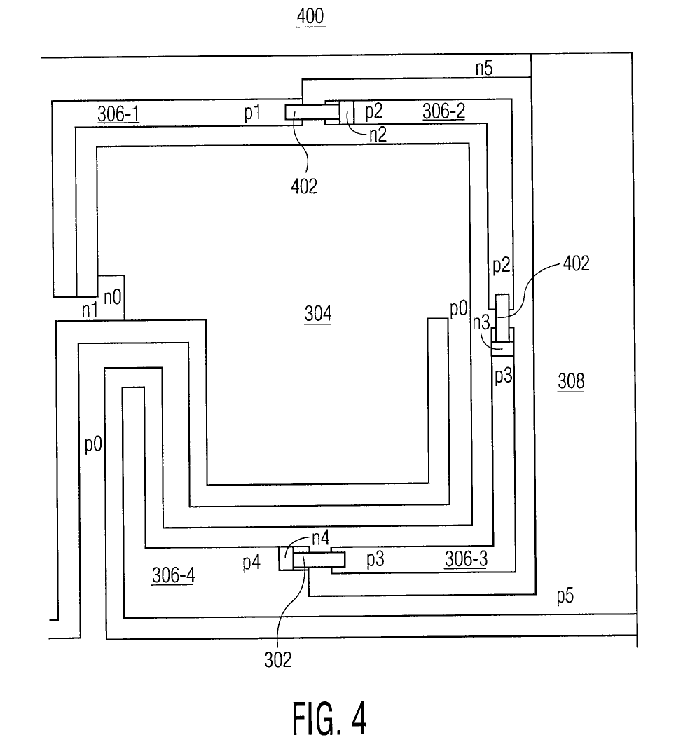

Referring to FIG. 4, a top-plan view diagram of a structure 400 of light emitting unit cell 300 is shown. Structure 400 illustrates the layout and electric connections of unit cell 300 of an example LED chip. First LED 304 is powered by a system power source through anode p0 and cathode n0. Cathode n0 is formed on a fabricated mesa-etched part of an n-type layer (for example of GaN) and is connected to the anode side of the power source.

A first LRD, 306-1, is connected to first LED 304 at cathodes n0, n1. Cathode n1 is the n-side of LRD 306-1 which is the same as cathode n0. A p-side of LRD 306-1, at anode p1, is connected to the n-side of LRD 306-2, at cathode n2, to form a series connection. LRDs 306-2, 306-3, 306-4 are similarly connected to each other. Because a p-type layer is formed as an upper layer and an n-type laser is formed as a lower layer, non-planar contacts 402 are provided for serial connection of LRDS 306-1, 306-2, 306-3, 306-4.

The p-side of LRD 306-4, at anode p4, is in contact with the p-side of second LED 308, at anode p5. The n-side of LED2, at cathode n5, is connected to cathodes n0, n1. Because the photocurrent received from LRDs 306 may be a fraction of the power supplied to first LED 304, it may be desirable for second LED 308 to be formed with an area that is smaller than first LED 304.

As shown in FIG. 4, LRDs 306 are formed proximate to first LED 304 such that LRDs 306 surround first LED 304, in order to receive TIR light from first LED 304. In general, LRDs 306 are formed from a same light emission structure (described below with respect to FIGS. 5A-5G) used to form first and second LEDs 304, 308. Because the LRD's 306 are connected in series and the series connected LRD's 306 are connected in parallel with second LED 308, the potential across any of the LRD's 306 cannot be sufficient to cause the LRD to emit light. Thus, each of the LRDs acts as a photodiode, converting received light into an electrical current.

Referring to FIGS. 5A-5G, an exemplary method of forming light emitting chip 500 is shown. As shown in FIG. 5A, buffer layer 504, n-type semiconductor layer 506, active layer 508 and p-type semiconductor layer 510 are sequentially grown on substrate 502, to form light emission structure 501.

Substrate 502 may be formed of a transparent material such as sapphire (for example with a (0001) plane orientation). Substrate 502 may be formed from other materials including, but not limited to, silicon carbide (SiC), GaN or magnesium aluminum oxide (MgAlO₂).

Buffer layer 504 may be used to enhance a lattice matching between substrate 502 and n-type semiconductor layer 506. Buffer layer 504 may be omitted depending on a process condition and diode characteristic. According to an exemplary embodiment, buffer layer 504 may be formed from about a 10 nm thickness undoped GaN semiconductor layer on a (0001) surface of sapphire substrate 502 for the lattice matching. In addition to GaN, buffer layer 504 may be formed from, but not limited to, (undoped) GaN, aluminum nitride (AlN), aluminum gallium nitride (AlGaN) or aluminum indium nitride (AlInN).

N-type semiconductor layer 506 and p-type semiconductor layer 510 may be formed of semiconductor materials including, but not limited to, AlₘGa₁₋ₘN (for 0≦m≦1), to emit blue light. According to an example embodiment, n-type semiconductor layer 506 of about 2 μm thickness may be grown from GaN semiconductor material doped with n-type conductive impurities, such as silicon (Si) or germanium (Ge). According to an example embodiment, p-type semiconductor layer 510 of about 200 nm thickness may be grown from GaN semiconductor material doped with p-type conductive impurities, such as magnesium (Mg), zinc (Zn) or beryllium (Be).

To produce light emitting chips for emitting other colors, n-type and p-type semiconductor layers 506, 510 may be formed from different materials. For example, to emit blue light: ZnSe or indium gallium nitride (InGaN) may be used. To emit green light: InGaN, GaP, aluminum gallium indium phosphide (AlGaInP) or aluminum gallium phosphide (AlGaP) may be used. To emit yellow light: gallium arsenide phosphide (GaAsP), AlGaInP or GaP may be used. To emit orange light: GaAsP, AlGaInP or GaP may be used. To emit red light: aluminum gallium arsenide (AlGaAs), GaAsP, AlGaInP or GaP may be used.

Active layer 508 may include a single quantum well (SQW) structure or a MQW structure. According to an exemplary embodiment, active layer 508 of about 50 nm total thickness may be formed from alternating layers of InGaN/GaN. Active layer 508 may be formed of semiconductor material including, but not limited to, InₘAlₙGa₁₋ₘ₋ₙN (for 0<m≦1, 0≦n≦1, 0<m+n≦1) or InₘGa₁₋ₘN (for 0<m<1). Active layer 508 may be omitted depending on a desired process condition and a desired diode characteristic. According to another embodiment, active layer 508 may be omitted for portions of the light emitting structure corresponding to the LEDs or to the LRDs. According to a further embodiment, light emitting structure 501 may be formed with different active layer materials for the portions corresponding to the respective LEDs and LRDs.

Buffer layer 504, n-type semiconductor layer 506, active layer 508 and p-type semiconductor layer 510 may be grown by using any suitable deposition process, including, but not limited to, metal organic chemical deposition (MOCVD) or molecular beam epitaxy (MBE).

As shown in FIG. 5B, after forming light emitting structure 501, insulating pattern 512 may be formed on p-type semiconductor layer 510, for example, by any suitable photolithographic technique.

According to an exemplary embodiment, a silicon dioxide (SiO₂) film (not shown) may be deposited on the p-type semiconductor layer 510 layer, for example, by chemical vapor deposition (CVD). A photoresist (not shown) may be subsequently spun on the SiO₂ film. A binary chromium (Cr) mask with a desired insulating pattern may be applied for patterning the photoresist. The photoresist may be exposed to ultraviolet (UV) light by a mask aligner or stepper and may be subsequently developed by a developer. The SiO₂ film may be etched through the photoresist by, for example, reactive ion etching (RIE) with insulating pattern 512.

The patterned SiO₂ film may be used as a mask for a GaN full etching process. All layers of light emitting structure 501 may be etched via the SiO₂ mask through to substrate 502. The SiO₂ film may be subsequently removed after the etching process is completed.

As shown in FIG. 5C, a GaN mesa-etching process is performed. According to an exemplary embodiment, a similar photolithographic method as described for the full etching process (shown in FIG. 5B) may be used for n-GaN mesa-etching. For example, a thickness of about 0.55 μm may be etched by RIE from a top of n-type semiconductor layer 506 on predetermined portions. The n-GaN mesa-etching may be performed to securely supply free electrons from n-type layer 506 to p-type layer 510 through the interface between the two layers.

The patterns for n-GaN mesa-etching may include: an entire n-electrode portion 514, a portion 516 of a first LED portion 520, and a portion 518 of each LRD portion 522. On each portion (514, 516, 518), a top 0.55 μm thickness may be etched away such that the n-type layer 506 is partially exposed.

As shown in FIG. 5D, a transparent electrode layer 528 may be deposited by any suitable process such as sputtering, CVD and evaporation. According to an exemplary embodiment, transparent electrode layer 528 is formed with a thickness of about 200 nm. Transparent electrode layer 528, may be formed from, for example, indium tin oxide (ITO), titanium (Ti), gold (Au), a combination of Ti and Au, tin oxide (SnO) or zinc oxide (ZnO). Transparent electrode layer 528 may be deposited and patterned on predetermined portions by any suitable photolithography process.

Transparent electrode layer 528 may be deposited to cover p-electrode portion 526, first LED portion 520 (except for the mesa-etched portion 516), LRD portion 522 (except for mesa-etched portion 518), and second LED portion 524. Transparent electrode layer 528 is desirably formed to be substantially transparent to light having a predetermined wavelength. Transparent electrode layer 528 may be formed so that light escaping from the underlying layer (p-type layer 510) may be effectively extracted and so that electrons are spread over transparent electrode layer 528 from p-type layer 510 to p-electrode portion 526. P-electrode portion 526 may also be formed from any suitable metallic materials, such as Au, copper (Cu), a combination of platinum (Pt) and Au, a combination of nickel (Ni) and Au or a combination of chromium (Cr) and Au, for example by sputtering, CVD and evaporation.

As shown in FIG. 5E, n-electrode portion 514 may be formed, for example, by any suitable photolithography process on the mesa-etched part of n-type layer 506, to provide an ohmic contact. According to an exemplary embodiment, n-electrode portion 514 is formed with a thickness of about 20 nm. The ohmic contact desirably includes a linear I-V curve and low resistance. N-electrode portion 514 may be formed from any suitable metallic materials, such as Au, Cu, a combination of Pt and Au or a combination of Ni and Au, for example by sputtering, CVD and evaporation. Alternatively, ITO may be used as n-electrode portion 514, in which case the patterning of n-electrode portion 514 may be performed together with the transparent electrode patterning (FIG. 5D).

As shown in FIG. 5F, passivation layer 530 may be formed to provide insulation between n-type layer 506 and p-type layer 510 at the series connection of LRD portions 522. Passivation layer 530 may help to prevent an electrical short circuit when bridge contact layer 532 (FIG. 5G) is formed between p-type layer 510 and an adjacent mesa-etched part of n-type layer 506. Passivation layer 530 may be formed, for example, from SiO₂ by a sputtering, CVD and/or an evaporation process.

As shown in FIG. 5G, bridge contact layer 532 is then formed to provide an electrical connection between p-type layer 510 on one side of LRD portion 522 and the mesa-etched n-type layer 506 (portion 518) on a side of an adjacent LRD portion 522, thus forming light emitting chip 500. Any metallic material, such as Au, Cu or Ni, may be used for bridge contact layers 532. Bridge contact layer 532 may be formed by any suitable process such as electroless/electro plating or sputtering and CVD.

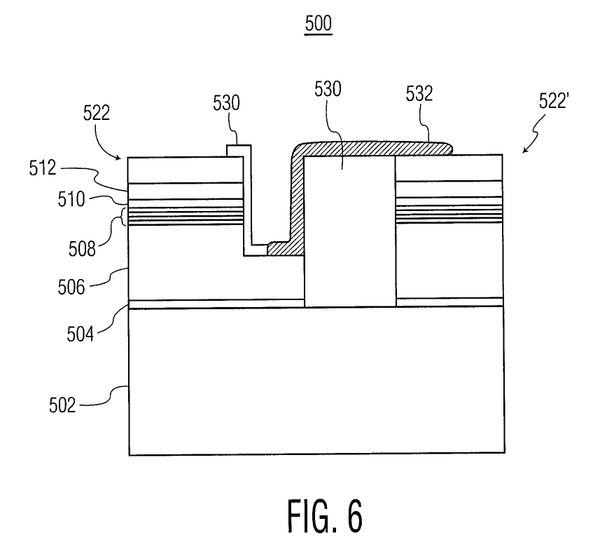

Referring to FIG. 6, cross-section diagram along lines 6-6′ of light emitting chip 500 is shown. Bridge contact layer 532 connects the mesa-etched n-type layer 506 on one side of one LRD 522 to a p-type layer 510 of an adjacent LRD 522. Bridge contact layer 532 is formed over passivation layer 530. Accordingly, photo-electrons created in one LRD 522 travel from n-type layer 506 to a p-type layer 510 of an adjacent LRD 522′ through bridge contact layer 532.

Next, a theoretical extraction efficiency (ηₑₓₜᵣ) for light emitting unit cell 300 (FIG. 3) is compared with a conventional extraction efficiency (ηₒ) for number m of LEDs 304, 308 (where m is an integer). For m LEDs 304, 308, extraction efficiency ηₑₓₜᵣ is shown in equation (4) as:

$$\begin{matrix}{η}_{extr} = {η}_{o} + {η}_{o} α ( 1 - {η}_{o} ) + … {η}_{o} {{α}^{m - 1} ( 1 - {η}_{o} )}^{m - 1} \\ = {η}_{o} \frac{1 - {{α}^{m} ( 1 - {η}_{o} )}^{m}}{1 - α ( 1 - {η}_{o} )}\end{matrix} \qquad ( 4 )$$

where the conversion efficiency (α) is the respective efficiencies for converting light to a photocurrent within LRDs 306.

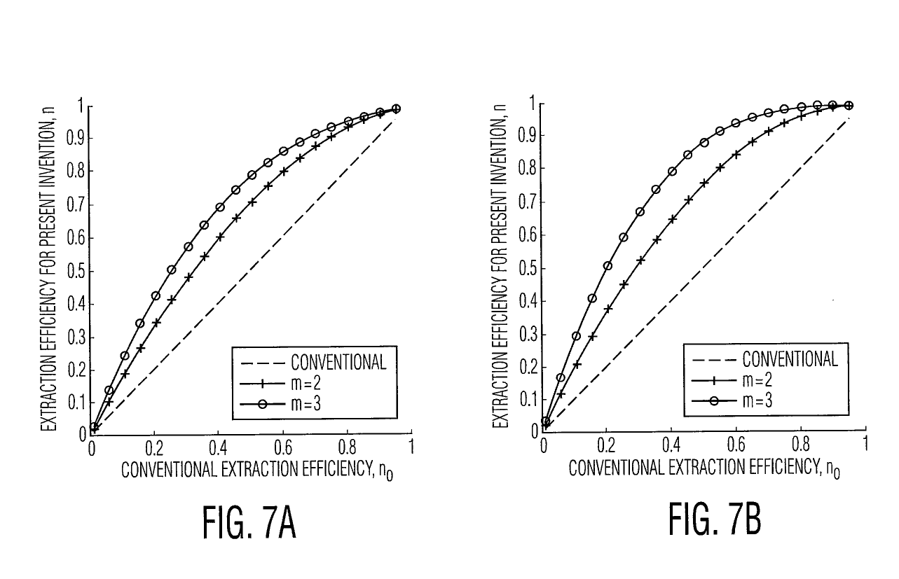

A summary of theoretical extraction efficiencies under different conversion efficiencies (α=0.8 and α=1.0) and a different number of LEDs 304, 308 (m=2, m=3) are shown in Table 1 below. Referring to FIGS. 7A and 7B, graphs are shown which summarizing the theoretical extraction efficiencies of Table 1. In particular, FIG. 7A shows the extraction efficiencies for α=0.8 and FIG. 7B shows the extraction efficiencies for α=1.0. As shown in FIGS. 7A and 7B and Table 1, the extraction efficiencies are improved by a ratio between about 1.4-2.3 as compared with the conventional extraction efficiency. In general, the extraction efficiency increases with an increasing number of LEDs 304, 308.

TABLE 1
Theoretical Extraction Efficiency for Light Emitting Unit Cell 300

| m | α | ηₒ | ηₑₓₜᵣ |
|---|---|---|---|
| 2 | 0.8 | 0.25 | 0.4 |
| | | 0.5 | 0.7 |
| | 1.0 | 0.25 | 0.4375 |
| | | 0.5 | 0.75 |
| 3 | 0.8 | 0.25 | 0.49 |
| | | 0.5 | 0.78 |
| | 1.0 | 0.25 | 0.5781 |
| | | 0.5 | 0.8750 |

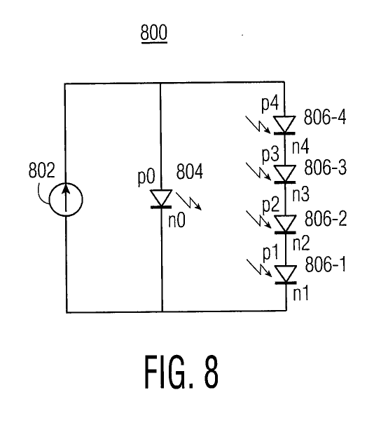

Referring next to FIG. 8, a circuit diagram of an exemplary light emitting unit cell 800 is shown. Light emitting unit cell 800 includes LED 804 connected in parallel with power source 802. Light emitting unit cell 800 also includes a plurality of light receiving diodes (LRDs) 806 which are optically coupled to LED 804 and are electrically connected in parallel with LED 804.

LRDs 806-1, 806-2, 806-3, 806-4 are connected to each other in series. Anode p4 of LRD 806-4 is electrically connected to anode p0 of LED 804. Cathode n1 of LRD 806-1 is electrically connected to cathode n0 of LED 804. Because LRDs 806 are serially connected, each LRD 806 is powered by a fraction of the received voltage (based on the number of LRDs 806). Consequently, none of the LRD's can emit light. Instead, each of the LRD's 806 operates as a photodiode.

In operation, LED 804 is powered by power source 802. LRDs 806 may absorb light trapped inside the layers of LED 804 (i.e., due to TIR) and convert the absorbed light to a photocurrent. The photocurrent generated in LRDs 806 is fed back to LED 804, to supply a photocurrent to light emitting unit cell 800. Because LRDs 806 are serially connected (and receive a fraction of the voltage), LRDs 806 may be configured to absorb the TIR light without emitting light. Accordingly, light emitting unit cell 800 may recycle photocurrent that would be lost due to TIR and apply the photocurrent to further power light emitting unit cell 800.

Although four LRDs 806 are shown in FIG. 8, it is understood by the skilled person that light emitting unit cell 800 may include two or more LRDs 806 configured to absorb TIR light from LED 804, to feed back a suitable photocurrent to LED 804.

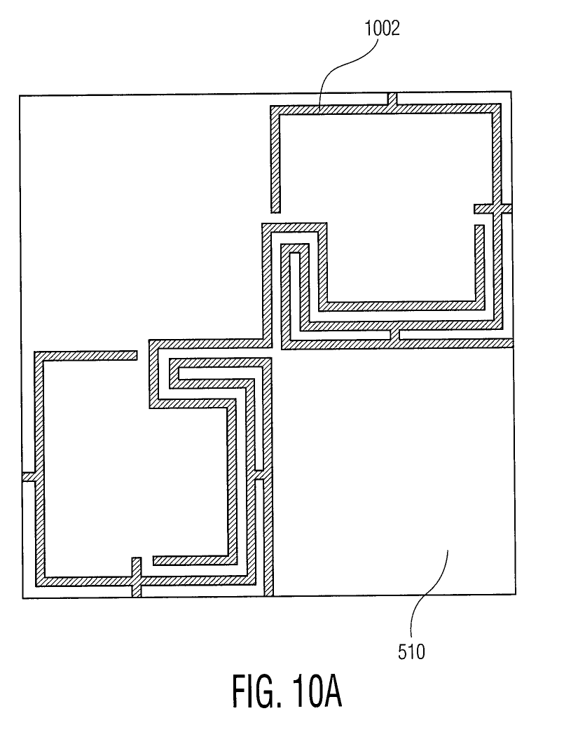

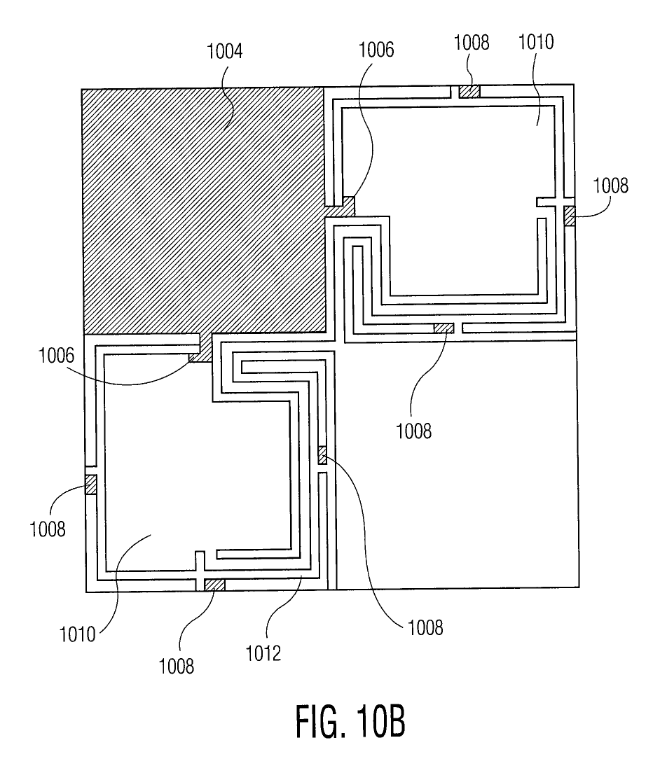

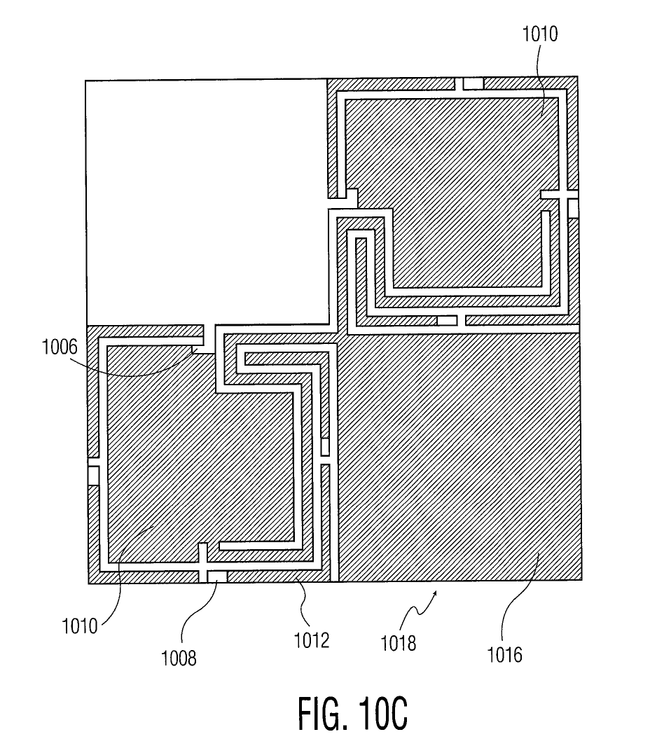

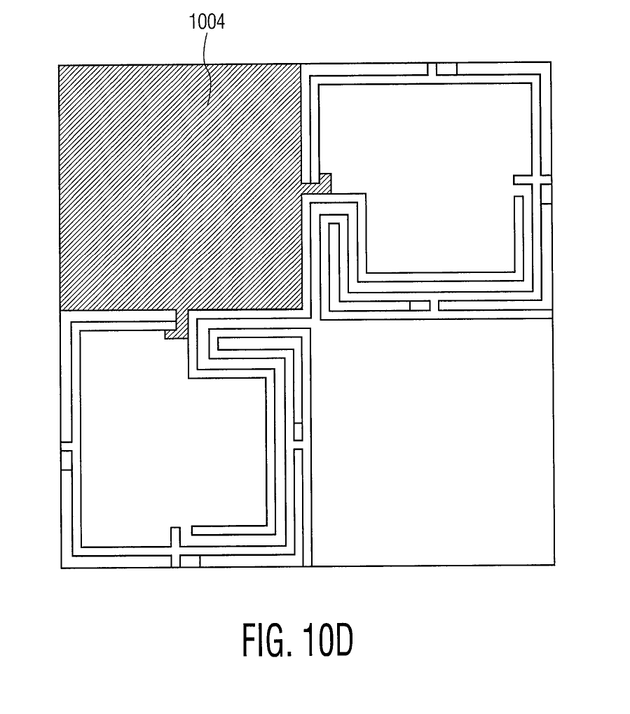

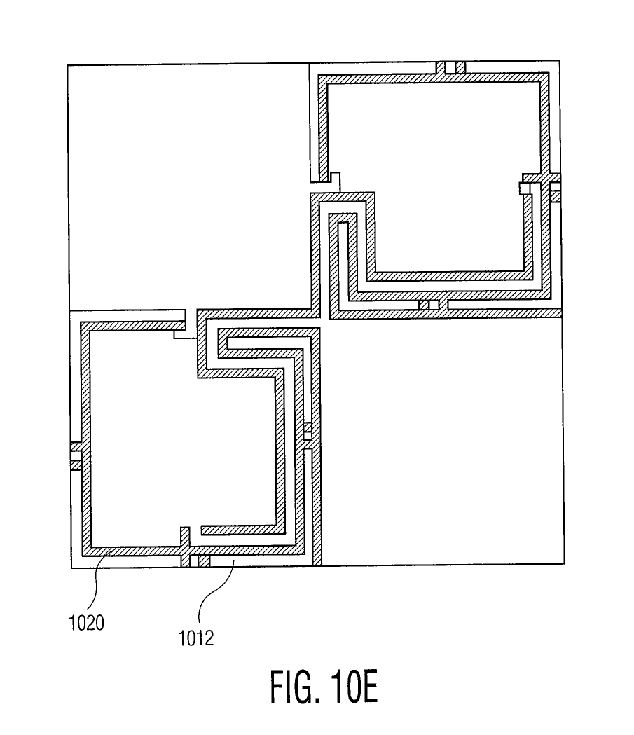

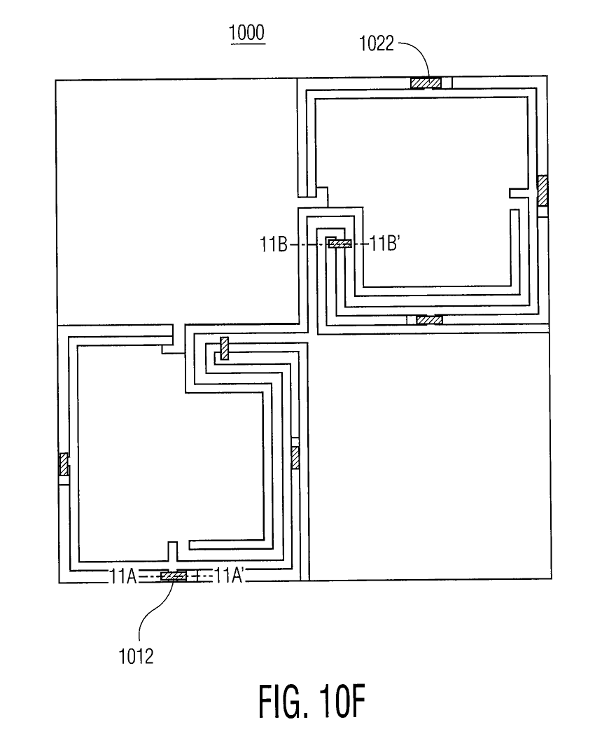

Although one light emitting unit cell 800 is shown in FIG. 8, an LED chip (described below with respect to FIGS. 10A-10F) may include a plurality of unit cells (such as described below with respect to FIG. 13), which is referred to herein as a micro-pixelated LED.

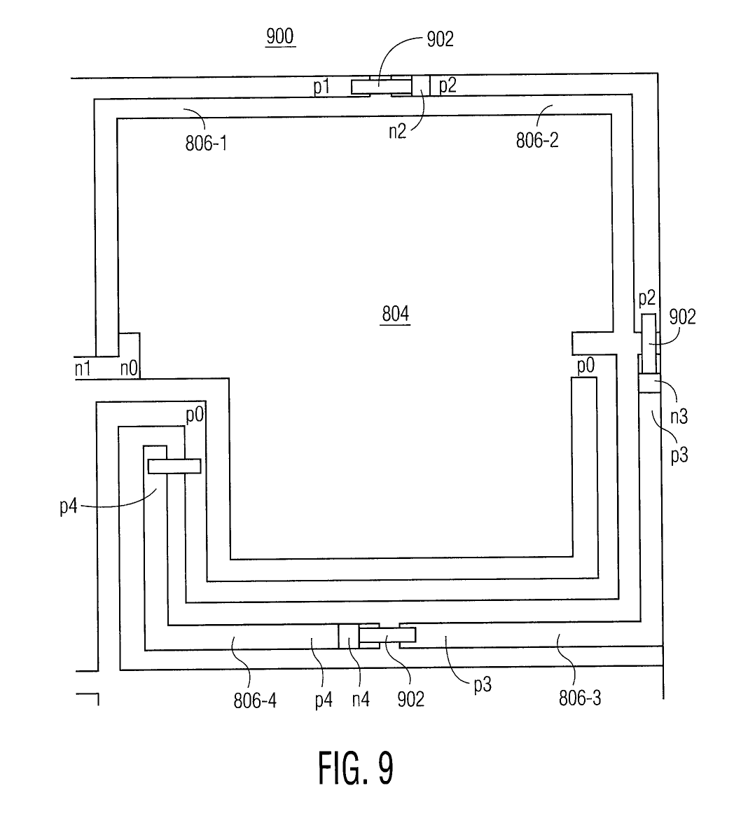

FIG. 9, shows a top-plan view diagram of a structure 900 of light emitting unit cell 800. Structure 900 illustrates the layout and electric connections of unit cell 800 of an example LED chip. LED 804 is powered by a system power source through anode p0 and cathode n0. Cathode n0 is formed on a fabricated mesa-etched part of an n-type layer (for example of GaN) and is connected to the anode side of the power source.

A first LRD, 806-1, is connected to LED 804 at respective cathodes n0, n1. A p-side of LRD 806-1, at anode p1, is connected to the n-side of LRD 806-2, at cathode n2, to form a series connection. LRDs 806-2, 806-3, 806-4 are similarly connected to each other. Because a p-type layer is formed as an upper layer and an n-type laser is formed as a lower layer, non-planar contact 902 is provided for serial connection of LRDs 806-1, 806-2, 806-3, 806-4.

The p-side of LRD 806-4, at anode p4, is in contact with the p-side of LED 804, at anode p0, and a cathode of the system power source. The n-side of LRD 806-1, at cathode n1, is also connected with an anode of the system power source.

As shown in FIG. 9, LRDs 806 are formed proximate to LED 804 such that LRDs 806 surround LED 804, in order to receive TIR light from LED 804. In general, LRDs 806 are formed from a same light emission structure (described below with respect to FIGS. 10A-10F) used to form LED 804.

Referring to FIGS. 5A and 10A-10F, an exemplary method of forming light emitting chip 1000 (FIG. 10F) is shown. In general, light emitting chip 1000 may be formed by a process similar to light emitting chip 500, the details of which are described above.

Light emitting chip 1000 may be formed from the same light emission structure 501 described above with light emitting chip 500. As described with respect to FIG. 5A, buffer layer 504, n-type semiconductor layer 506, active layer 508 and p-type semiconductor layer 510 are sequentially grown on substrate 502, to form light emission structure 501.

As shown in FIG. 10A, after forming light emitting structure 501, insulating pattern 1002 may be formed on p-type semiconductor layer 510, for example, by any suitable photolithographic technique. For example, as described above, a patterned SiO₂ film may be used as a mask for a GaN full etching process. The SiO₂ film may be etched through the photoresist with insulating pattern 1002. All layers of light emitting structure 501 may be etched via the SiO₂ mask through to substrate 502. The SiO₂ film may be subsequently removed after the etching process is completed.

As shown in FIG. 10B, a GaN mesa-etching process is performed. According to an exemplary embodiment, a similar photolithographic method as described for the full etching process (shown in FIG. 10A) may be used for n-GaN mesa-etching. The n-GaN mesa-etching may be performed to securely supply free electrons from n-type layer 506 to p-type layer 510 through the interface between the two layers. The patterns for n-GaN mesa-etching may include: an entire n-electrode portion 1004, a portion 1006 of LED portion 1010, and a portion 1008 of each LRD portion 1012. On each portion (1004, 1006, 1008), a top 0.55 μm thickness, for example, may be etched away such that the n-type layer 506 is partially exposed.

As shown in FIG. 10C, a transparent electrode layer 1018 may be deposited and patterned. Transparent electrode layer 1018 may be deposited to cover p-electrode portion 1016, LED portion 1010 (except for the mesa-etched portion 1006) and LRD portion 1012 (except for mesa-etched portion 1008). Transparent electrode layer 1018 may be formed so that light escaping from the underlying layer (p-type layer 510) may be effectively extracted and so that electrons are spread over transparent electrode layer 1018 from p-type layer 510 to p-electrode portion 1016.

As shown in FIG. 10D, n-electrode portion 1004 may be formed, for example, by any suitable photolithography process on the mesa-etched part of n-type layer 506, to provide an ohmic contact. The ohmic contact desirably includes a linear I-V curve and low resistance.

As shown in FIG. 10E, passivation layer 1020 may be formed to provide insulation between n-type layer 506 and p-type layer 510 at the series connection of LRD portions 522. Passivation layer 1020 may help to prevent an electrical short circuit when bridge contact layer 1022 (FIG. 10F) is formed between p-type layer 510 and an adjacent mesa-etched part of n-type layer 506.

As shown in FIG. 10F, bridge contact layer 1022 is formed to provide an electrical connection between p-type layer 510 on one side of LRD portion 1012 and the mesa-etched n-type layer 506 (portion 1008) on a side of an adjacent LRD portion 1012, thus forming light emitting chip 1000.

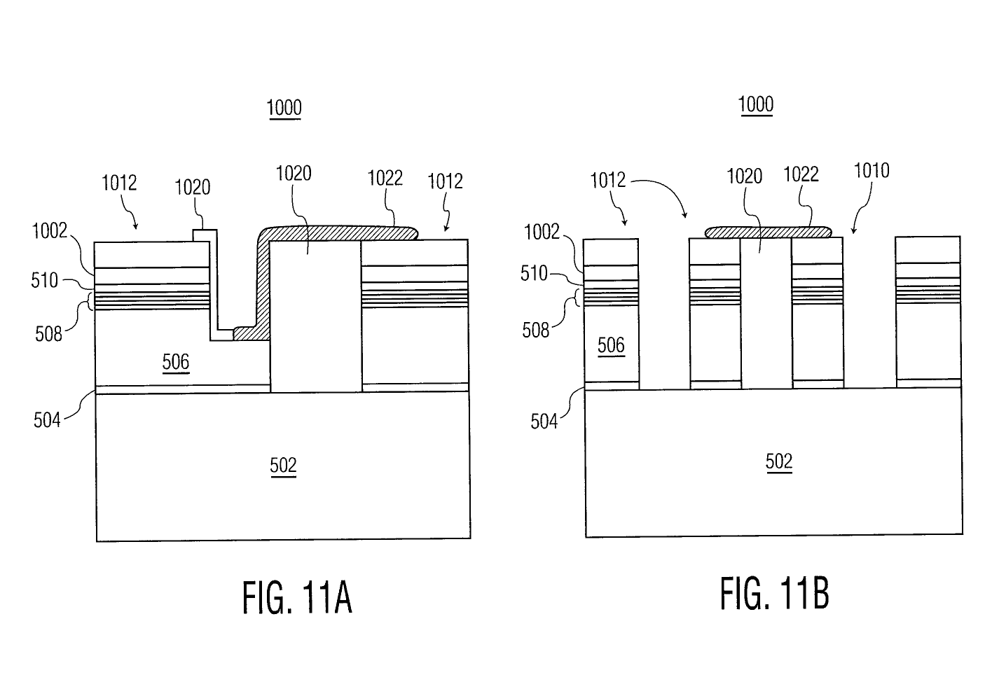

Referring to FIGS. 11A and 11B, cross-section diagrams of light emitting chip 1000 are shown. In particular, FIG. 11A is a cross-section diagram along lines 11A-11A′; and FIG. 11B is a cross-section diagram along lines 11B-11B′.

Along line 11A-11A′, bridge contact layer 1022 connects the mesa-etched n-type layer 506 on one side of one LRD 1012 to a p-type layer 510 of an adjacent LRD 1012. Bridge contact layer 1022 is formed over passivation layer 1020. Accordingly, photo-electrons created in one LRD 1012 travel from n-type layer 506 to a p-type layer 510 of an adjacent LRD 1012 through bridge contact 1022. Along line 11B-11B′, bridge contact layer 1022 bridges over passivation layer 1020 to connect a p-type layer 510 of LRD 1012 to a p-type layer 510 of LED portion 1010.

Next, a theoretical extraction efficiency (ηₑₓₜᵣ) for light emitting unit cell 800 (FIG. 8) is compared with a conventional extraction efficiency (ηₒ). For unit cell 800, extraction efficiency ηₑₓₜᵣ, based on Kirchhoff's law, is shown in equation (5) as:

$${η}_{extr} = {η}_{o} \frac{{η}_{o}}{1 - α ( 1 - {η}_{o} )} \qquad ( 5 )$$

where the conventional extraction efficiency (ηₒ) and the conversion efficiency (α) are the respective efficiencies for converting light to a photocurrent within LRDs 806. In equation (5), for the sake of simplicity, any series resistances of LED 804 and LRDs 806 have been neglected.

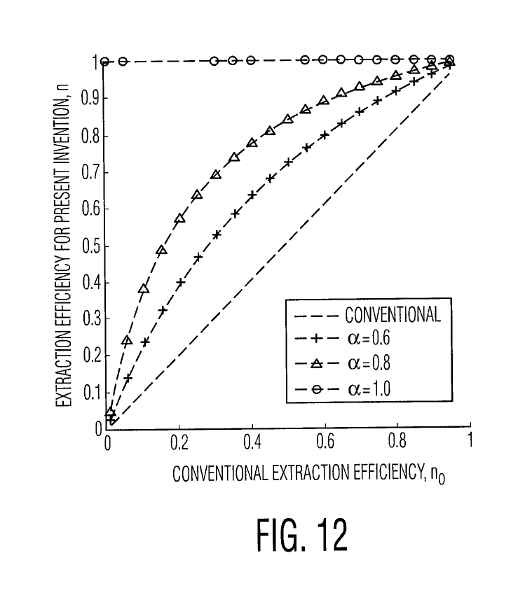

A summary of theoretical extraction efficiencies under different conversion efficiencies (α=0.6, α=0.8 and α=1.0) are shown in Table 2 below. Referring to FIG. 12, a graph is shown which summarizing the theoretical extraction efficiencies of Table 2. As shown in FIG. 12 and Table 2, the extraction efficiencies are improved by a ratio between about 1.4-4.0 as compared with the conventional extraction efficiency. In general, the extraction efficiency increases with increasing conversion efficiency.

TABLE 2
Theoretical Extraction Efficiency for Light Emitting Unit Cell 800

| α | ηₒ | ηₑₓₜᵣ |
|---|---|---|
| 0.6 | 0.25 | 0.4545 |
| | 0.5 | 0.7143 |
| 0.8 | 0.25 | 0.6250 |
| | 0.5 | 0.8333 |
| 1.0 | 0.25 | 1.0 |
| | 0.5 | 1.0 |

Referring to FIG. 13, a micro-pixelated LED 1300 is shown. Micro-pixelated LED 1300 is similar to light emitting chips 500, 1000 (respective FIGS. 5G and 10F), except that micro-pixelated LED 1300 includes LED arrays 1310, having a plurality of light emitting unit cells 1312. Each of the light emitting unit cells 1312 may be similar to light emitting unit cell 300 or 800 (respective FIGS. 3 and 8) described above.

Micro-pixelated LED 1300 includes an n-electrode 1302 formed on an exposed upper surface of n-type layer 1304. A p-electrode 1306 is formed on an upper surface of transparent electrode 1308.

Although p-side up configurations (where light is emitted from the p-type layer) of light emitting unit cells 300, 800 are described above, n-side up configurations (where light is emitted from the n-type layer) of unit cells 300, 800 may also be used. Light emitting unit cells 300, 800 of the present invention may be applied to any configuration which provides photocurrent recycling.

An n-side up configuration may be formed, for example, by direct growth of a p-type layer and an n-type layer in reverse order. An n-side up configuration may also be formed by growing a p-side up configuration first and further depositing a suitable metal layer (such as Au and/or Sn)) and an appropriate submount (such as Au-coated Si) on top of the p-type layer. A laser lift-off (LLO) process may be used to detach the n-type layer from the substrate. For example, a laser beam (such as a krypton fluoride (KrF) laser beam) may be applied through the transparent substrate side to detach the n-type layer from the substrate.

An n-side up configuration may also be formed using a flip-chip technique. In this configuration, a p-side up configuration is initially formed, except that the transparent electrode may be replaced by a thick reflective electrode layer. The device may be flipped and bonded onto a submount, typically a Si wafer, by using a bonding material such as solder, a Au bump or a Au ball. In this device, light is emitted from the substrate bottom surface.

Several embodiments of the invention have been described herein. It is understood that the present invention is not limited to these embodiments and that different embodiments may be used together. In addition, it is understood that any conventional technique such as surface roughening, grating, volume hologram and photonic crystal may be incorporated with embodiments of the present invention, for example, for further enhancement of the extraction efficiency.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A light emitting chip comprising:
a light emission structure comprising:
a p-type semiconductor layer,
an n-type semiconductor layer, and
an active layer between the p-type semiconductor layer and the n-type semiconductor layer; and
at least one light emitting unit comprising:
a light emitting diode (LED) portion formed from the light emission structure, and
a plurality of light receiving diode (LRD) portions formed from the light emission structure, the plurality of LRD portions serially connected and configured to surround the LED portion, the plurality of LRD portions optically coupled to the LED portion to receive total internal reflection (TIR) light from the LED portion and configured to convert the TIR light to a photocurrent.

2. The light emitting chip according to claim 1, wherein the plurality of LRD portions are electrically connected in parallel with the LED portion.

3. The light emitting chip according to claim 1, wherein the at least one light emitting unit includes a further LED portion formed from the light emission structure, and the plurality of LRD portions are electrically connected in parallel with the further LED portion.

4. The light emitting chip according to claim 1, wherein the at least one light emitting unit including a plurality of light emitting units arranged to form an LED array.

5. The light emitting chip according to claim 1, wherein the light emission structure is configured to emit light via the p-type semiconductor layer.

6. The light emitting chip according to claim 1, wherein the light emission structure is configured to emit light via the n-type semiconductor layer.

7. The light emitting chip according to claim 1, wherein the active layer includes a single quantum well (SQW) structure or a multi quantum well (MQW) structure.

8. The light emitting chip according to claim 1, wherein the at least one light emitting unit includes:
an electrode layer formed on one of the p-type semiconductor layer and the n-type semiconductor layer, the electrode layer being substantially transparent to light having a predetermined wavelength,
a first electrode coupled to the n-type semiconductor layer, and
a second electrode coupled to the p-type semiconductor layer.

9. The light emitting chip according to claim 1, wherein the active layer is formed from a semiconductor material including at least one of InₘAlₙGa₁₋ₘ₋ₙN (where 0<m≦1, 0≦n≦1, 0<m+n≦1) or InₘGa₁₋ₘN (where 0<m<1).

10. The light emitting chip according to claim 1, wherein the p-type semiconductor layer and the n-type semiconductor layer are formed from a semiconductor material including at least one of AlₘGa₁₋ₘN (where 0≦m≦1), ZnSe, InGaN, GaP, AlGaInP, AlGaP, GaAsP or AlGaAs.

11. A light emitting unit cell comprising:
a first light emitting diode (LED) electrically connected to a power source;
a plurality of light receiving diodes (LRDs) connected in series, the plurality of LRDs optically coupled to the first LED to receive total internal reflection (TIR) light from the first LED and configured to convert the TIR light to a photocurrent; and
a second LED electrically connected in parallel with the plurality of LRDs.

12. The light emitting unit cell according to claim 11, wherein the photocurrent is applied to the second LED as a further power source.

13. The light emitting unit cell according to claim 11, wherein a cathode of one of the plurality of LRDs is electrically connected to a cathode of the first LED.

14. The light emitting unit cell according to claim 11, wherein each of the plurality of LRDs is configured to receive the TIR light without emitting light.

15. The light emitting unit cell according to claim 11, further comprising:
a further plurality of LRDS optically coupled to the second LED to receive further TIR light from the second LED and to convert the further TIR light to a further photocurrent; and
a third LED electrically connected in parallel with the further plurality of LRDs.

16. A light emitting unit cell comprising:
a light emitting diode (LED) electrically connected to a power source; and
a plurality of light receiving diodes (LRDs) connected in series, the plurality of LRDs optically coupled to the LED to receive total internal reflection (TIR) light from the LED and configured to convert the TIR light to a photocurrent,
wherein the plurality of LRDs are electrically coupled to the LED to feed back the photocurrent to the LED.

17. The light emitting unit cell according to claim 16, wherein each of the plurality of LRDs is configured to receive the TIR light without emitting light.

18. The light emitting unit cell according to claim 16, wherein the plurality of LRDs are electrically connected in parallel with the LED.

19. A method of forming a light emitting chip, the method comprising:
forming a light emission structure including a p-type semiconductor layer, an n-type semiconductor layer and an active layer between the p-type semiconductor layer and the n-type semiconductor layer; and
forming at least one light emitting unit from the light emission structure including:
forming a light emitting diode (LED) portion, and
forming a plurality of light receiving diode (LRD) portions to surround the LED portion, the plurality of LRD portions being serially connected to each other and optically coupled to the LED portion,
wherein the plurality of LRD portions receive total internal reflection (TIR) light from the LED portion and convert the TIR light to a photocurrent.

20. The method according to claim 19, the forming of the light emission structure including:
forming an electrode layer on one of the p-type semiconductor layer and the n-type semiconductor layer, the electrode layer being substantially transparent to light having a predetermined wavelength,
forming a first electrode to be electrically coupled to the n-type semiconductor layer, and
forming a second electrode to be electrically coupled to the p-type semiconductor layer.

21. The method according to claim 19, wherein the plurality of LRD portions are formed to be electrically connected in parallel with the LED portion.

22. The method according to claim 19, the forming of the at least one light emitting unit including:
forming a further LED portion, and
forming the plurality of LRD portions to be electrically connected in parallel with the further LED portion.

23. The method according to claim 19, wherein the at least one light emitting unit includes a plurality of light emitting units and the light emitting chip is formed to including the plurality of light emitting units arranged as an LED array.
